(19) United States
(12) Patent Application Publication
(10) Pub. No.: US 2003/0201069 A1
(43) Pub. Date: Oct. 30, 2003

(54) Tunable focus ring for plasma processing

(76) Inventor: Wayne L. Johnson, Phoenix, AZ (US)

Correspondence Address: PILLSBURY WINTHROP, LLP, P.O. BOX 10500, MCLEAN, VA, 22102, US

(21) Appl. No.: 10/378,992

(22) Filed: Mar. 5, 2003

Related U.S. Application Data
(63) Continuation of application No. PCT/US01/28318, filed on Sep. 12, 2001.
(60) Provisional application No. 60/233,623, filed on Sep. 18, 2000.

(51) Int. Cl. H01L 21/306; C23C 16/00

(52) U.S. Cl. 156/345.43; 156/345.44; 156/345.45; 156/345.47; 118/723 E

(57) ABSTRACT

A focus ring (200) and related assembly for a plasma reactor system (100, 400) for processing a workpiece (176) having an outer edge and an upper surface. The assembly has a focus ring support surface (173) arranged around the workpiece perimeter and a ring electrode (210) arranged atop the focus ring support surface. An insulating focus ring (200) is arranged atop the ring electrode. In one embodiment, a first RF power supply (180) is electrically connected to the focus ring electrode and a tuning network (220) is arranged between the first RF power supply and the ring electrode. Methods of forming a plasma (130) and processing a workpiece in an optimized way, as well as a plasma reactor system for accomplishing the same, are also disclosed.

This is a Continuation of International Application No. PCT/US01/2831, which was filed on Sep. 12, 2001 and claims the benefit of U.S. Provisional Application No. 60/233,623, which was filed Sep. 18, 2000, the contents of which are incorporated herein by reference.

### BACKGROUND OF THE INVENTION

The present invention relates to plasma processing, and in particular relates to apparatus for and methods of improving plasma processing uniformity.

Ionized gas or “plasma” may be used during processing and fabrication of semiconductor devices, flat panel displays and other products requiring etching or deposition of materials. Plasma may be used to etch or remove material from semiconductor integrated circuit wafers, or sputter or deposit material onto a semiconducting, conducting or insulating surface. Creating a plasma for use in manufacturing or fabrication processes is typically done by introducing a low-pressure process gas into a chamber surrounding a workpiece such as an integrated circuit (IC) wafer. A fraction of the molecular and/or atomic species present in the chamber is ionized by a radio frequency energy (power) source to form a plasma. The plasma then flows over and interacts with the workpiece. The chamber is used to maintain the low pressures required to form the plasma, to provide a clean environment for processing and to serve as a structure for supporting one or more radio frequency energy sources.

Plasma may be created from a low-pressure process gas by inducing an electron flow that ionizes individual gas molecules by transferring kinetic energy through individual electron-gas molecule collisions. Typically, electrons are accelerated in an electric field such as one produced by radio frequency (RF) energy. This RF energy may be low frequency (i.e. below 550 KHz), high frequency (e.g., 13.56 MHz), or microwave frequency (e.g., 2.45 GHz).

The two main types of dry etching in semiconductor processing are plasma enhanced etching and reactive ion etching (RIE). A plasma etching system generally includes a radio frequency energy source and a plurality (typically a pair) of electrodes for coupling power to form and sustain a plasma within the vacuum chamber. A plasma is generated between the electrodes, and the workpiece (i.e., substrate or wafer) to be processed is arranged parallel to one of the electrodes. The chemical species in the plasma are determined by the source gas(es) used and the desired process to be carried out.

A problem that has plagued prior art plasma reactor systems is the control of the plasma to obtain uniform etching and coating (hereinafter either process will be referred to as “plasma processing”). In plasma reactors, the degree of processing uniformity is determined by the design of the overall system, and in particular by the design of the RF feed electronics and the associated control circuitry. To this end, several different approaches are used to improve plasma processing. One approach to increase the plasma density (in order to increase plasma processing rate) is to increase the fundamental RF drive frequency of the RF power supply from the traditional value of 13.56 MHz to 60 MHz or higher. In doing so, successful improvements to process performance (in particular process rate) have been achieved. However, this has come at the expense of the complexity of reactor design and the process uniformity. One approach to achieving high process rates while enabling a means to improve process uniformity is to employ a multi-segment electrode, but this also tends to increase the complexity and cost of the reactor design. An example of such a system is described in greater detail in pending U.S. patent application Serial No. 60/185,069, entitled “Multi-zone RF electrode for field/plasma uniformity control in capacitive plasma sources.”

A second, less complex approach is to utilize a tunable “focus ring” within the plasma reactor chamber that allows the plasma and plasma chemistry to be adjusted proximate to the edge of the workpiece in a manner that improves plasma process uniformity. Historically, the focus ring (which resides on the chuck or workpiece susceptor) has been designed and utilized to enable repeatable placement of the workpiece in the same location upon the chuck. However, it has been found that the focus ring also affects the process at the edge of the workpiece. Therefore, if designed properly (i.e., material, shape, proximity to workpiece edge, etc.), a focus ring may be used to effect a more uniform process.

However, current focus ring technology allows for only gross adjustments of the plasma processing uniformity. These adjustment increments tend to be too large to account for subtle changes in wafer film stack composition and integrated circuit design present on the wafer being processed. This can lead to inadequate etch uniformity and thus elevated scrap rates. In other words, a particular design for the focus ring pertains to a predetermined process condition or range of process conditions, and can therefore be regarded as unduly restrictive. Moreover, differential etching or coating is sometimes desirable. Current plasma reactors are capable only of etching or coating to a flat uniformity specification across the entire wafer surface, and often do so with difficulty.

### BRIEF SUMMARY OF THE INVENTION

The invention is a method and apparatus for controlling a plasma formed in a capacitively or inductively coupled plasma reactor. In particular, RF power is delivered through a tuning network to a tunable annular focus ring that surrounds a workpiece (e.g., wafer) and serves to control the spatial distribution of the electric field and plasma density. The focus ring thereby reduces plasma edge effects and improves process uniformity.

Accordingly, a first aspect of the invention is a focus ring assembly apparatus for a plasma reactor system for processing a workpiece having an outer edge and an upper surface. The assembly comprises a focus ring support surface arranged around the workpiece outer edge and a ring electrode arranged atop the focus ring support surface. An insulating focus ring is arranged atop the ring electrode. A first RF power supply is electrically connected to the focus ring electrode. A tuning network is arranged between the first RF power supply and the ring electrode.

A second aspect of the invention is a plasma reactor system for processing a workpiece. The system comprises a reactor chamber with an interior region capable of supporting a plasma. An upper electrode is arranged in the interior region near an upper wall. A workpiece support member is arranged adjacent a lower wall and comprises a lower electrode having an upper surface for supporting the workpiece, an insulating region surrounding the lower electrode, and a base surrounding the insulating region. The base has a focus ring support surface. An upper electrode RF power supply is electrically connected to the upper electrode. The system also includes a focus ring assembly apparatus as described immediately above. The system preferably includes a RF power supply that is electrically connected to the lower electrode. This RF power supply may be the same one connected to the ring electrode, or may be a separate RF power supply. Where the RF power supplies are separate, a tuning network circuit is not necessary.

A third aspect of the invention is a method of plasma processing a workpiece to a desired standard with a reactor system having a reactor chamber with a focus ring arranged adjacent the workpiece outer edge and made of a material M and having a profile P, an inner R_{I} and an outer radius R_{O}, R_{I} and R_{O} being referred to collectively as R. The focus ring is arranged a vertical distance D relative to the workpiece upper surface. A ring electrode is arranged adjacent the focus ring and is electrically connected to a tuning network having an inductor with inductance I and a variable capacitor with variable capacitance C, the system thus having a set A of variable parameters {P, R, M, I, C, D}. The method comprises the steps of first, setting parameters A={P, R, M, I, C, D} to initial values, and then processing one or more workpieces while varying one or more of the process parameters to determine an optimized set of process parameters

A*={P*, R*, M*, I*, C*, D*} that provide the desired processing to within a predetermined standard.

A fourth aspect of the invention is providing a workpiece to be processed in the reactor chamber of the present invention, then forming an optimized plasma with the process chamber using the set of optimized process parameters determined in the manner described above and in more detail below, and then processing the workpiece with the optimized plasma.

### BRIEF DESCRIPTION OF THE SEVERAL VIEWS OF THE DRAWING

FIG. 1A is a cross-sectional schematic diagram of the plasma reactor system of the present invention, including a first embodiment of a focus ring arranged around the workpiece;

FIG. 1B is a close-up cross-sectional view of the workpiece support member of the system of FIG. 1A;

FIGS. 2A-2D are a plan view (FIG. 2A) and cross-sectional views (FIGS. 2B-2D) of different focus ring shapes with different cross-sectional profiles;

FIG. 3 is a schematic circuit diagram of the tuning network of FIG. 1;

FIG. 4A is a close-up view of a portion of the system of FIG. 1, showing the workpiece support member, focus ring, tuning network, lower electrode power supply and match network;

FIG. 4B is a close-up view of a portion of a second embodiment of the plasma reactor system of the present invention similar to that of FIG. 1, wherein the focus ring electrode and the lower electrode have separate RF power supplies and match networks;

FIG. 5A is a close-up view of a portion of a third embodiment of the plasma reactor system of the present invention similar to that of FIG. 1, wherein the focus ring is adjustably arranged around the workpiece;

FIG. 5B is a close-up cross-sectional view of a preferred embodiment of the adjustable shaft of the reactor system of FIG. 5A; and

FIG. 6 is a flow diagram of the steps for deducing the optimum parameters and for processing a workpiece using the optimum parameters with the plasma processing system of the present invention.

### DETAILED DESCRIPTION OF THE INVENTION

The present invention relates to plasma processing, and in particular relates to apparatus for and methods of improving plasma processing uniformity.

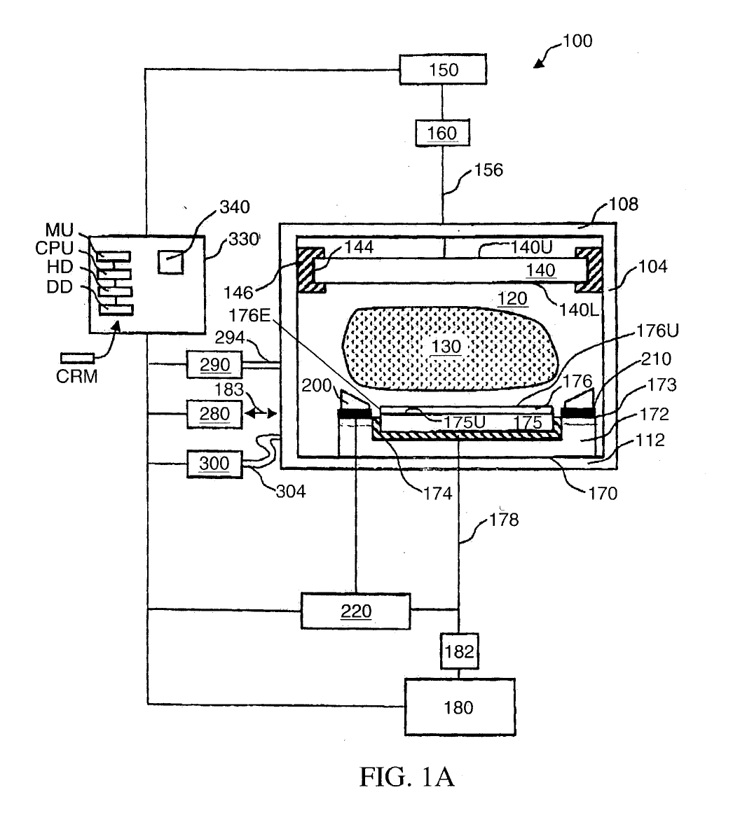

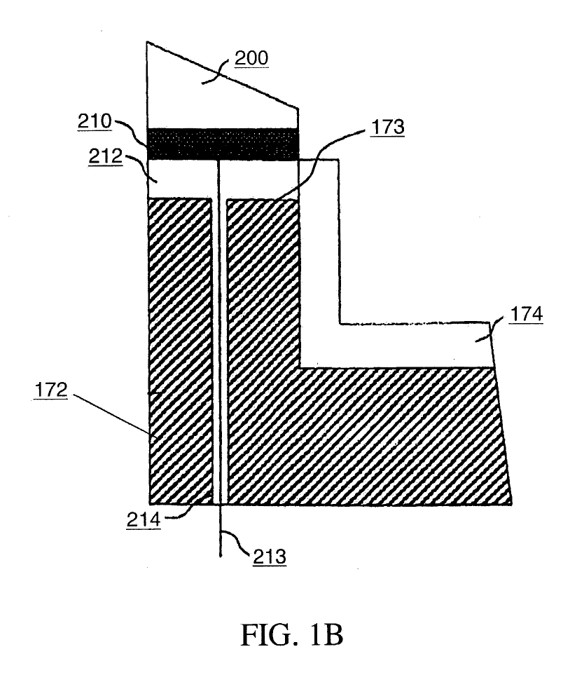

With reference to FIG. 1A, plasma reactor system 100 comprises a reactor chamber with sidewalls 104, an upper wall 108 and a lower wall 112 defining an interior region 120 capable of supporting a plasma 130. Arranged within interior region 120 near upper wall 108 is an electrode 140 having an upper surface 140U, a lower surface 140L and a periphery 144. Electrode 140 is referred to as the “plasma electrode.” Insulators 146 are arranged between electrode periphery 144 and sidewalls 104 to electrically isolate electrode 140 from the chamber. System 100 further includes a RF power supply 150 electrically connected to upper surface 140U of electrode 140 via a RF feed line 156 that passes through upper wall 108. A match network 160 is preferably arranged in RF feed line 156 between electrode 140 and RF power supply 150. Match network 160 is tuned to provide the best match to the load presented by plasma 130 formed within interior region 120 so as to optimize power transfer to the plasma.

With reference also to FIG. 1B, reactor system 100 further includes a workpiece support member 170 arranged adjacent lower wall 112 opposite electrode 140. Workpiece support member 170 includes a base 172 having an upper annular focus ring support surface 173, an insulating region 174 and a lower electrode 175 having an upper surface 175U capable of supporting a workpiece 176, such as a wafer, to be processed (e.g., etched or coated) by means of plasma 130. Workpiece 176 has an outer edge 176E and an upper surface 176U. Insulating region 174 is filled with an insulating material such as ceramic or quartz, and electrically insulates base 172 from lower electrode 175. Electrically connected to lower electrode 175 via a RF feed line 178 is a lower electrode RF power supply 180 for biasing the lower electrode. Preferably included between RF power supply 180 and lower electrode 175 in RF feed line 178 is a match network 182.

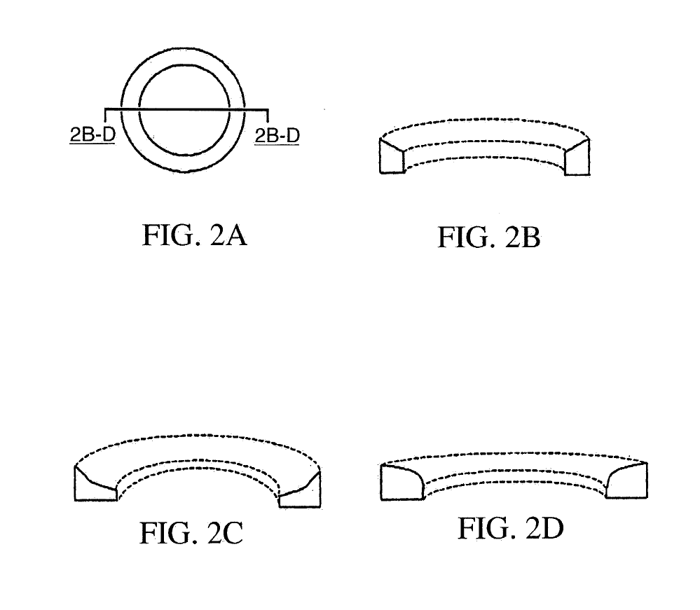

With continuing reference to FIGS. 1A and 1B, also included in plasma reactor 100 is an annular focus ring 200 arranged atop surface 173 of workpiece support member base 172. Focus ring 200 is an annular ring of nonconducting material surrounding but electrically isolated from workpiece 176. Focus ring 200 is preferably made from quartz, but may also be made of silicon, silicon carbide, alumina, etc. or any of many insulating materials or insulating material compositions or semiconductors. Focus ring 200 may be made with any one of a number of cross-sectional profiles, such as the linear radially increasing thickness profile shown in FIGS. 1A and 1B or any of the exemplary profiles of FIGS. 2A-2D. Alternatively, the focus ring profile need not be uniform around the entire periphery of the focus ring. Such a variable profile focus ring can provide differential etching and edge-effect compensation. A peripherally variable profile focus ring is useful to compensate for azimuthal asymmetries introduced by other aspects of the reactor design, i.e., field/plasma asymmetries.

Arranged between surface 173 and focus ring 200 is a ring electrode 210 and an insulating layer 212, wherein the insulating layer electrically isolates the ring electrode from conductive base 172. Base 172 and chamber walls 104, 108 and 112 are preferably connected to ground. Ring electrode 210 is electrically connected to a tuning network 220 via inner conductor 213 of a transmission line 214. Tuning network 220 is electrically connected to lower electrode RF power supply 180 via a match network 182. The combination of focus ring 200, ring electrode 210, tuning network 220, match network 182 and RF power supply 180 constitute a focus ring assembly within system 100.

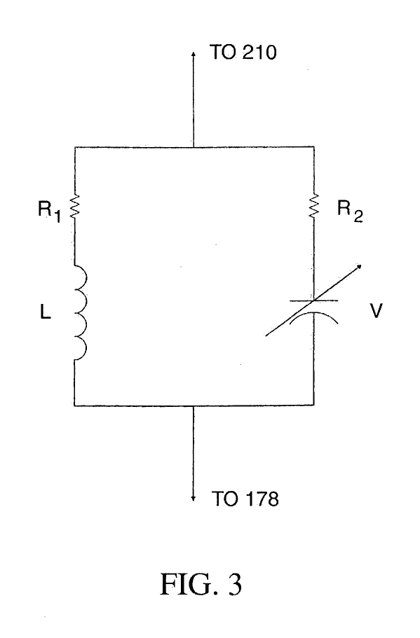

With reference now to FIG. 3, tuning network 220 can be an electronic circuit comprising a variable capacitor V with variable capacitance C and an inductor L with inductance I arranged in parallel with the variable capacitor. Tunable capacitor V is a commercially available variable capacitor whose range of capacitance C is chosen based upon the bias frequency applied to lower electrode 175 and focus ring electrode via lower electrode RF power supply 180, and the subsequent load impedance. FIG. 3 also shows two resistors R₁ and R₂ that represent the effective series resistance of the variable impedance circuit. Exemplary values for each component is as follows: I˜60 nH, C˜0.1 μF, R₁˜0.05 Ω and R₂˜0.05 Ω.

The inductance I of inductor L is preferably chosen according to the same principles. Design and selection of the electrical components in tuning network 220 is well known to those ordinary in the art.

Tuning network 220 is tuned by selecting the values for I and C that provide the best power signal conditioning for a given profile for focus ring 200, workpiece composition, and etch specification. Tuning network 220 is preferably designed using the following criteria: (1) the phase angle variation across the network, i.e., the phase difference from one side to the other of the parallel circuit formed by inductor L and capacitor V, should be negligible (less than 1-10% the RF period) throughout the entire tuning range, and (2) the tuning network should be capable of diverting power to focus ring electrode 210 up to the power delivered to the chuck (or lower) electrode 175 (i.e. P_{ring}≦P_{LE}).

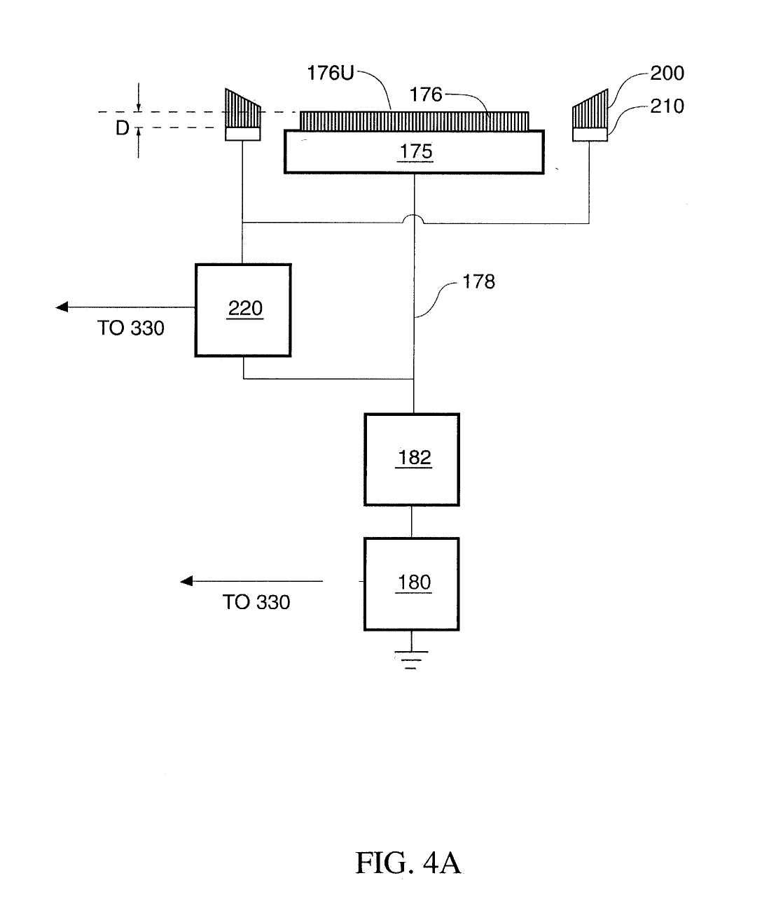

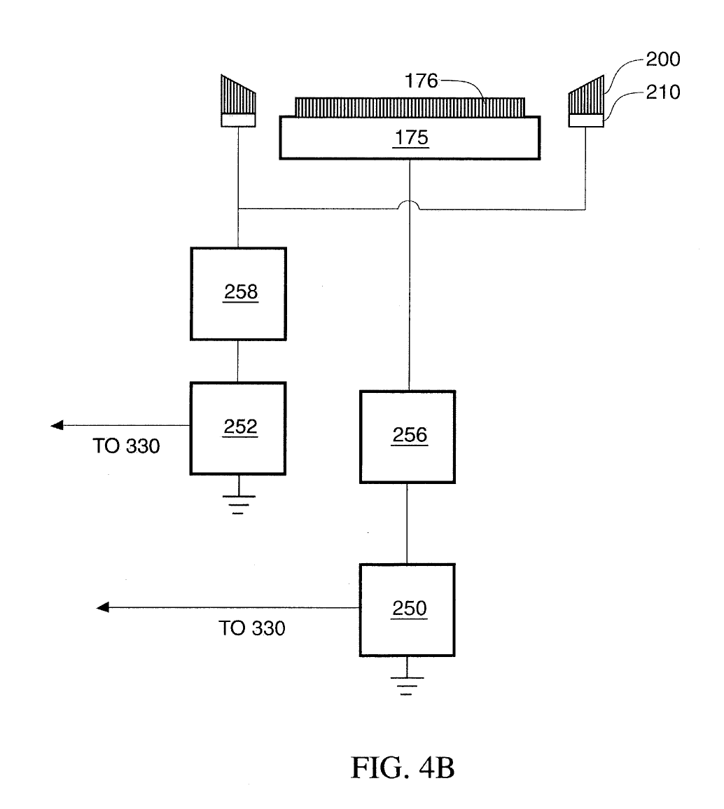

With reference now also to FIG. 4A, in a first embodiment of system 100, lower electrode 175 and ring electrode 210 are RF biased using a single RF power supply 180. In this case, tuning network 220 serves as a variable impedance element that partitions the relative power delivered to lower electrode 175 and ring electrode 210 such that the ring electrode power P_{ring} does not exceed the lower electrode power P_{LE}, i.e. P_{ring}≦P_{LE}. RF power supply 180 is impedance matched to the corresponding load through match network 182, wherein the electrical load comprises various electrical elements including tuning network 220, ring electrode 210 and lower electrode 175 and plasma 130.

The actual value of variable capacitor V is dependent upon the reactive part of the plasma. The voltage amplitude and phase on the ring electrode relative to the voltage on the chuck is strongly dependent upon the inter-electrode coupling, particularly through the plasma. In past experiments, it has been found the chuck/plasma impedance (as “seen” by the chuck match network) to be approximately 1+j80 Ω. For a real plasma impedance of 1 Ω, the phase difference between the voltage on the ring electrode and the voltage on the chuck is negligible, whereas the relative voltage difference may be varied between plus or minus 10 volts (the chuck voltage nominally being 1500V) for capacitances ranging from 0.05 to 0.2 μF. Similarly, for a real plasma impedance of 10 Ω, the phase difference between the voltage on the ring electrode and the voltage on the chuck is negligible, whereas the relative voltage difference may be varied between plus or minus 30 volts (nominally 1500V on the chuck) for capacitances ranging from 0.05 to 0.2 μF. And lastly, for a real plasma impedance of 100 Ω, the phase difference between the voltage on the ring electrode and the voltage on the chuck is approximately 45 degrees, whereas the relative voltage difference may be varied between plus or minus approximately 500 volts (nominally 1500V on the chuck) for capacitances ranging from 0.05 to 0.2 μF. Therefore, the phase difference between the voltage on the bias (focus) ring electrode and the chuck electrode will be strongly determined by the inter-electrode coupling, particularly through the plasma. When there exists weak coupling (i.e. greater than 100 Ω), the phase difference can become significant (i.e. as large as 180 degrees).

With reference now to FIG. 4B, in a second embodiment of system 100, lower electrode 175 and ring electrode 210 are individually powered through their own separate RF power supplies 250 and 252, respectively, with respective match networks 256 and 258.

Match networks 182, 256 and 258 are preferably conventional automatically tuned match networks. Such networks typically include a phase-magnitude detector (not shown) for observing forward and reflected power, and a match network controller (not shown) for controlling impedance matching. The match network controller, in response to measurements of the forward and reflected power, commands stepper motors (not shown) within the match network and operatively connected to a plurality of variable capacitors to match the load impedance by adjusting the phase angle shift from one side to the other of components L and V. The actual value of variable capacitor V is dependent upon the reactive part of the plasma, however, the same response characteristics to follow are noted. The voltage amplitude and phase on the ring electrode relative to the voltage on the chuck is strongly dependent upon the inter-electrode coupling, particularly through the plasma. In past experiments, we have found the chuck/plasma impedance (as “seen” by the chuck match network) to be approximately 1+j80. For a real plasma impedance of 1 Ω, the phase difference between the voltage on the ring electrode and the voltage on the chuck is negligible, whereas the relative voltage difference may be varied between plus or minus 10 volts (nominally 1500 volts on the chuck) for capacitances ranging from 0.05 to 0.2 μF. Similarly, for a real plasma impedance of 10 Ω, the phase difference between the voltage on the ring electrode and the voltage on the chuck is negligible, whereas the relative voltage difference may be varied between plus or minus 30 volts (nominally 1500 volts on the chuck) for capacitances ranging from 0.05 to 0.2 μF. And lastly, for a real plasma impedance of 100 Ω, the phase difference between the voltage on the ring electrode and the voltage on the chuck is approximately 45 degrees, whereas the relative voltage difference may be varied between plus or minus approximately 500 volts (nominally 1500 volts on the chuck) for capacitances ranging from 0.05 to 0.2 μF. Therefore, the phase difference between the voltage on the bias (focus) ring electrode and the chuck electrode will be strongly determined by the inter-electrode coupling, particularly through the plasma. When there exists weak coupling (i.e., greater than 100 Ω), the phase difference can become significant (i.e., as large as 180 degrees).

In addition to measuring the forward and reflected powers at the output of match networks 182, 256 and 258, the forward and reflected power can be measured at the output of the tuning network 220 for the embodiment shown in FIG. 4A. Measured powers can be used for subsequent adjustment of tuning network 220 to enable redistribution of chuck electrode power. Forward and reflected powers are measured using dual directional couplers and power meters, both of which and their methods of use are well-known to those skilled in the art.

With reference again to FIG. 1, system 100 also includes a workpiece handling system 280 in operative communication with plasma chamber 102 (see arrow 183) and workpiece support member 170, for placing workpieces 176 onto and removing workpieces 176 from workpiece support member 170. Also included is a gas supply system 290 in pneumatic communication with chamber 104 via a gas supply line 294 for supplying gas to chamber interior 120 to purge the chamber, and to provide chemical constituents for the respective process and to create plasma 130. The particular gases included in gas supply system 290 depend on the application. However, for plasma etching applications, gas supply system 290 preferably supplies such gases as chlorine, hydrogen-bromide, octafluorocyclobutane, and various other fluorocarbon compounds, etc. For chemical vapor deposition applications, gas supply system 290 preferably supplies silane, ammonia, tungsten-tetrachloride, titanium-tetrachloride, and the like.

Further included in system 100 is a vacuum system 300 in pneumatic communication with chamber 104 via a vacuum line 304.

System 100 also includes a main control system 330, which is in electronic communication with and controls and coordinates the operation of workpiece handling system 280, gas supply system 290, vacuum system 300, RF power supplies 150 and 180, and tuning network 220 through electrical signals. Main control system 330 thus controls the operation of system 100 and the plasma processing of workpieces 176 in the system, as described in greater detail below.

In a preferred embodiment, main control system 330 is a computer with a memory unit MU having both random-access memory (RAM) and read-only memory (ROM), a central processing unit CPU with a microprocessor (e.g., a PENTIUM™ processor from Intel Corporation), and a hard disk HD, all electrically connected. Hard disk HD serves as a secondary computer-readable storage medium, and may be, for example, a hard disk drive for storing information corresponding to instructions for control system 330 to carry out the present invention, as described below. Control system 330 also preferably includes a disk drive DD, electrically connected to hard disk HD, memory unit MU and central processing unit CPU, wherein the disk drive is capable of accepting and reading (and even writing to) a computer-readable medium CRM, such as a floppy disk or compact disk (CD), on which is stored information corresponding to instructions for control system 330 to carry out the present invention. It is also preferable that control system 330 has data acquisition and control capability. A suitable control system 330 is a computer, such as a DELL PRECISION WORKSTATION 610™, available from Dell Corporation, Dallas, Tex.

System 100 also preferably includes a database 340 electrically connected to or alternatively integral to control system 330 for storing data pertaining to the plasma processing of workpiece 176, and for also including predetermined sets of instructions (e.g., computer software) for operating system 100 via control system 330 to process the workpieces.

Adjustable Focus Ring Embodiment

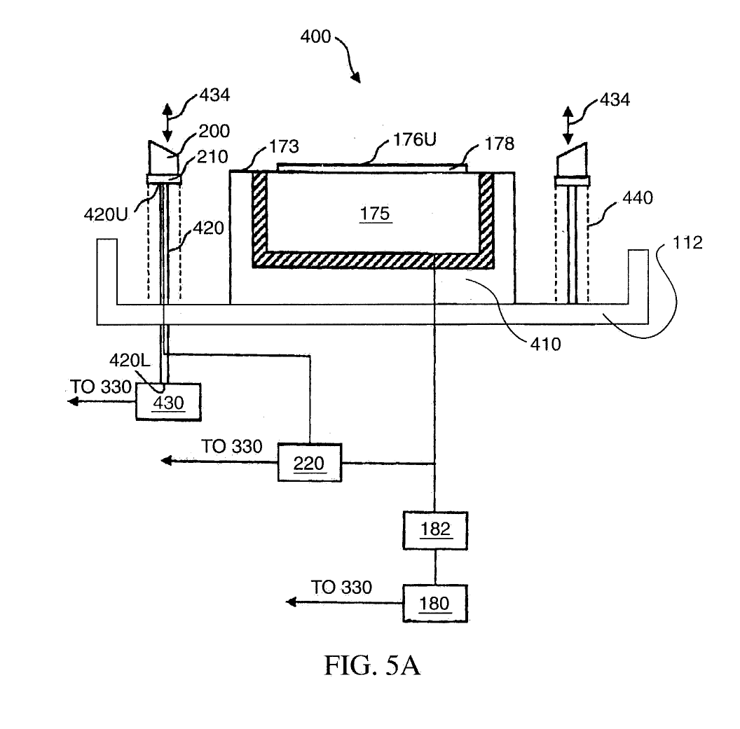

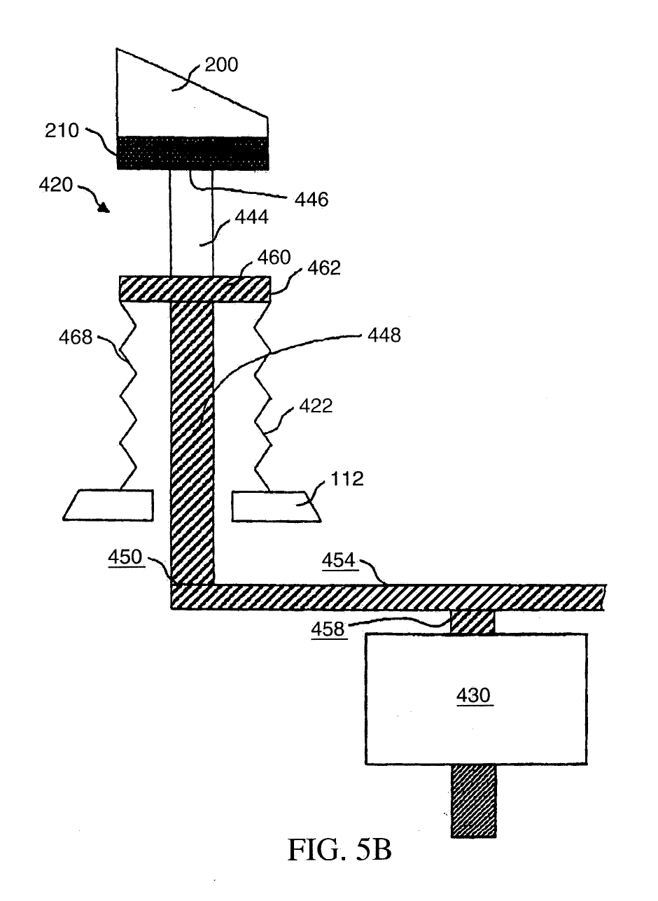

With reference now to FIG. 5A, an alternate embodiment of system 100 having an adjustable focus ring is now described. FIG. 5A is a close up of a portion of a plasma reactor system 400 showing the differences between system 100 and system 400. System 400 includes a workpiece support member 410 that has an upper annular support surface 173, but this surface is not used to support ring electrode 210 and focus ring 200. Instead, one or more separate adjustable shafts 420 each having an upper end 420U serving as a focus ring support surface and a lower end 420L are used. Ring electrode 210 is supported at upper end 420U, and focus ring 200 is arranged atop the ring electrode. Lower end 420L of at least one of shafts 420 is operatively connected to a translational device (e.g., a drive motor) 430 which raises and lowers the one or more shafts 420 (e.g., via the appropriate gearing mechanism), thereby adjusting the vertical distance D of focus ring 200 from upper surface 176U of workpiece 176, as indicated by arrows 434. Shafts 420 may be housed in a hollow stationary pedestal-type housing 440, as indicated by the dotted line. Shafts 420 may be moved independently to tilt focus ring 220, if necessary, to achieve a desired processing effect.

With reference now to FIG. 5B, there is shown a preferred embodiment for adjustable shaft 420, wherein the adjustable shaft comprises an upper portion 444 with an upper end 446 and made of an insulating, non-contaminating material. Upper end 446 supports ring electrode 210. Shaft 420 further comprises a lower portion 448 with a lower end 450. Attached to lower end 450 is a translational support arm 454 in operative communication with translational device 430. Operable communication may be achieved between arm 454 and device 430 via a drive shaft 458.

Arranged between upper portion 444 and lower portion 448 is a sealing member 460 with a perimeter 462. Attached between perimeter 462 and lower wall 112 is a bellows 468 surrounding lower portion 448 of shaft 420, that expands and contracts with the vertical (i.e., y-direction) movement of shaft 420. Upper and lower portions of shaft 420 can be different shafts joined together. Also, shaft 420 and translational support arm 454 can be a unitary structure.

Method of Operation

With reference again to FIG. 1 and system 100 (or to system 400 of FIG. 5), in operation, upon command from control system 330 and in accordance with the process instructions stored in memory unit MU or computer readable medium CRM, RF power supply 150 delivers electrical power up to 5 kW to upper electrode 140 via RF feed line 156. Simultaneously therewith, lower electrode RF power supply 180 delivers electrical power up to 3 kW to lower electrode 175 via RF feed line 178. The RF energy applied to the electrodes 140 and 175 in the presence of process gases introduced by gas supply system 290 via an electrical signal from control system 330 at a pressure of 1 mTorr-10 Torr ignites and forms plasma 130 in interior region 120 between the electrodes. Simultaneously with providing power to electrodes 140 and 175, RF power supply 180 delivers RF power to tuning network 220 that is equal to or less than that delivered to electrode 175. The electrical properties of tuning network 220 (i.e. inductance I of inductor L and variable capacitance C of capacitor V) coupled with the remainder of the electrical circuit (i.e. match network, lower electrode, plasma, etc.) determines the split of power between lower electrode 175 and ring electrode 210. Focus ring 200 controls the spatial distribution of the electric field and plasma density associated with plasma 130 around the outer edge, or peripheral portion, of workpiece 176. Through an empirical process or design of experiments (DOE) methodology, tuning network 220 can be adjusted and optimized to reduce workpiece processing edge effects and improve process uniformity. This may include adjusting tuning network 220 to provide differential plasma processing. In the present invention, the notion of plasma processing to achieve a desired degree of uniformity (or to reduce process non-uniformity) includes the concept of differential processing, in that the amount of uniformity desired is considered relative to a predetermined standard, which may be a single threshold value or a spatially varying functional threshold.

Optimizing the Plasma Processing Parameters

System 100 includes a number of parameters that may be modified to optimize the behavior of focus ring 200 to affect plasma processing uniformity. These parameters include: the cross-sectional profile P of focus ring 200, the inner and outer radii R=(R_{I}, R_{O}) of focus ring 200 relative to workpiece 176, the material M making up focus ring 200, the inductance I of inductor L, the capacitance value C of variable capacitor V, and the vertical distance D of focus ring 200 from the workpiece upper surface 176U (see FIG. 3A). These parameters can be represented as a set of process parameters, namely, A={P, R, M, I, C, D}. Any of the parameters within A may be combined and varied together to achieve or approach a desired workpiece uniformity requirement, including differential wafer etching.

In the second embodiment of system 100 shown in FIG. 4B, focus ring electrode 210 is powered by a separate power supply 252 operating at a frequency that may be different from that applied to the upper electrode or the lower electrode. It may further be operated at the same frequency as the lower electrode, but at a different phase. RF power supplies 250 and 252 are controlled by control system 220 electrically connected thereto.

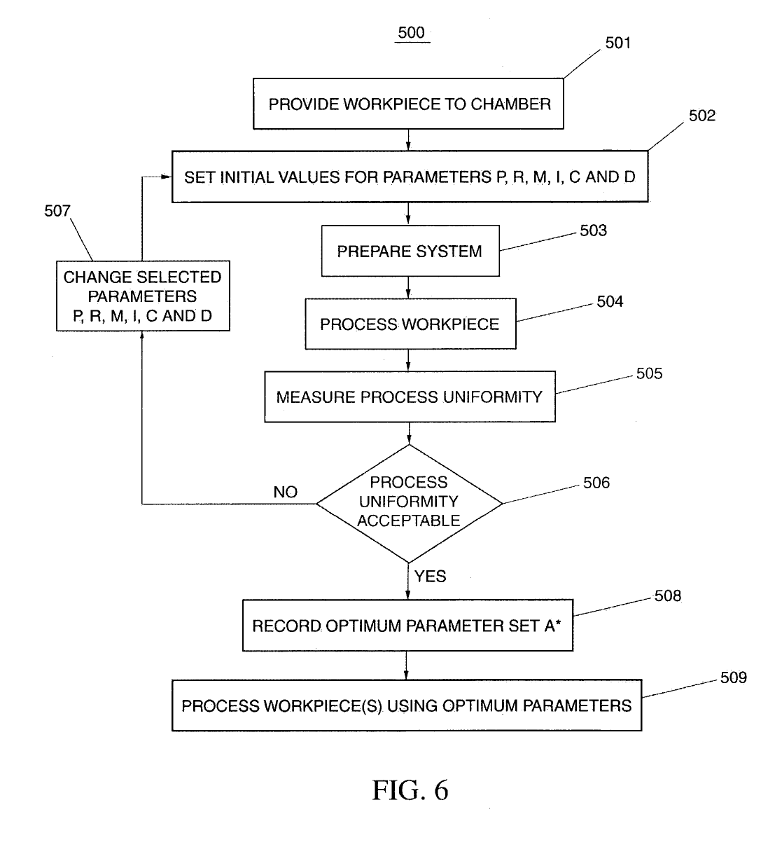

With reference now to FIG. 6 and flow diagram 500 therein, a method of empirically characterizing the process parameter set A={P, R, M, I, C, D} to provide optimal plasma processing is now described. In step 501, workpiece 176 is placed in chamber 104 upon upper surface 175U of electrode 175 by workpiece handling system 280. Next, in step 502, parameters in set A are set to initial values. The initial set of parameter values could be nominally set to values close to what are known to be acceptable operating values for the particular plasma process to be carried out.

Next, in step 503, system 100 (or system 400) is prepared in accordance with the initially set parameters by vacuum pump system 300 pumping down reactor chamber 102 in anticipation of forming plasma 130 in interior region 120. Concurrently, gas supply system 290 is directed by control system 330 to provide gas to interior region 120 according to a predetermined gas supply mixture recipe. Further, RF power supply systems 150 and 180 are directed by control system 330 to provide power to their respective electrodes 140 and 175. The interaction of the capacitively-coupled electrodes and gas creates a “first” plasma 130 corresponding to the process parameters, that is used to plasma process workpiece 176. In the next step 504, the workpiece is plasma processed, and then in step 505, the processing uniformity is measured. The process uniformity is based on the highest process (e.g., etch) rate minus the lowest process (e.g., etch) rate divided by two times the mean process (e.g., etch) rate across all of the data points as measured across workpiece 176. Uniformity measurements may be made interferometrically using known techniques.

The next step 506 inquires whether the process uniformity is acceptable. This preferably involves comparing the measured process uniformity to a predetermined standard in the form of a threshold value (e.g., less than 3%) or a functional threshold that accounts for desired processing profile (e.g., a differential etch across the workpiece). If the process uniformity is not acceptable, then in step 507, one or more of the parameters P, R, M, I, C and D are varied. In general, preparing the system for the next test requires replacement of the existing workpiece 176 with a new workpiece. In this manner, each of the parameters may be independently varied to assess its affect and sensitivity to the process. Thereafter, a series of experiments may be performed to locate the optimal arrangement of these parameters,

A*={P*, R*, M*, I*, C*, D*}. Moreover, RF field models for a vacuum may be used to give some direction in the design of the focus ring material, focus ring shape and profile, and the relative RF power delivered to the ring electrode and chuck electrode (such models might include ANSYS E-M fields model or High Frequency Structural Simulator (HFSS) available from the Hewlett-Packard Corporation).

Thus, in step 507, operational parameters P, R, M, I, C, D are recalculated using empirical methods or DOE methodology with the goal of converging on an optimum set of operational parameters A={P*, R*, M*, I*, C*}. DOE experiments and vacuum fields models may be used to establish an empirical relationship between the process uniformity and the respective independent parameters. These relationships may be used to define a set of equations or a single real-valued function describing the relationship between the process uniformity and the governing independent parameters that is amenable to non-linear optimization techniques (used to determine a function minimum) such as the Method of Steepest Descent or any suitable method described in the literature on mathematical theory.

Steps 503-505 are repeated until the optimum operation parameter set A* is converged upon.

f the process uniformity is deemed acceptable in query step 506, then the process proceeds to step 508, which involves recording optimum parameter set A* (e.g., in memory unit MU of control system 330) for subsequent use in processing workpieces.

In the last step 509, the optimum set of parameters A* is used to form an optimized plasma 130 used to process workpieces to achieve a high degree of process uniformity when processing the workpieces.

The many features and advantages of the present invention are apparent from the detailed specification and thus it is intended by the appended claims to cover all such features and advantages of the described method that follow in the true spirit and scope of the invention. Further, since numerous modifications and changes will readily occur to those of ordinary skill in the art, it is not desired to limit the invention to the exact construction and operation illustrated and described. Moreover, the methods and apparatus of the present invention, like related apparatus and methods used in the semiconductor arts that are complex in nature, are often best practiced by empirically determining the appropriate values of the operating process parameters, or by conducting computer simulations to arrive at the optimum process parameters for a given application. Accordingly, all suitable modifications and equivalents should be considered as falling within the spirit and scope of the invention.

What is claimed is:

1. A focus ring assembly apparatus for a plasma reactor system for processing a workpiece having an outer edge and an upper surface, comprising:
a) a ring electrode;
b) a focus ring made of nonconductive material arranged atop, and insulated from, said ring electrode;
c) a first RF power supply electrically connected to said focus ring electrode; and
d) a tuning network arranged between said first RF power supply and said ring electrode.

2. The apparatus according to claim 1, wherein said tuning network includes a variable capacitor and an inductor.

3. An apparatus according to claim 1, further including a match network between said first RF power supply and said tuning network.

4. The apparatus according to claim 1, further comprising a workpiece support member having a lower electrode capable of supporting the workpiece, a base surrounding said lower electrode and including a focus ring support surface, and an insulating region between said lower electrode and said base, wherein said focus ring support surface supports said ring electrode.

5. The apparatus according to claim 4, wherein said first power supply is electrically connected to said lower electrode.

6. An apparatus according to claim 1, further comprising an adjustable shaft supporting said ring electrode and operatively connected to a drive motor for moving the shaft so as to change the position of the focus ring relative to the workpiece upper surface.

7. A focus ring assembly apparatus for a plasma reactor system for processing a workpiece having an outer edge and an upper surface, comprising:
a) a focus ring support surface arranged around the workpiece outer edge,
wherein said focus ring support surface is part of a workpiece support member having a lower electrode capable of supporting the workpiece, a base surrounding said lower electrode, and an insulating region between said lower electrode and said base, wherein said focus ring support surface is part of said base;
b) a ring electrode arranged atop said focus ring support surface;
c) a focus ring made of nonconductive material arranged atop said ring electrode;
d) a first RF power supply electrically connected to said focus ring electrode; and
e) a second RF power supply electrically connected to said lower electrode.

8. A plasma reactor system for processing a workpiece having an upper surface and an outer edge, comprising:
a) a reactor chamber having an upper wall, a lower wall and sidewalls that define an interior region and capable of supporting a plasma;
b) an upper electrode arranged in said interior region near said upper wall;
c) a workpiece support member arranged adjacent said lower wall and comprising a lower electrode having an upper surface for supporting the workpiece, an insulating region surrounding the lower electrode, and a base surrounding the insulating region, the base having a focus ring support surface;
d) an upper electrode RF power supply electrically connected to said upper electrode; and
e) the focus ring assembly apparatus according to claim 4, wherein said first RF power supply is also electrically connected to said lower electrode.

9. The reactor system according to claim 8, further including a match network arranged between said upper electrode power supply and said upper electrode.

10. The reactor system according to claim 8, further including means for adjusting the vertical position of said focus ring relative to the workpiece upper surface.

11. The reactor system according to claim 8, further including:
a) a gas supply system in pneumatic communication with said interior region;
b) a vacuum system in pneumatic communication with said interior region; and
c) a control system electrically connected to said upper electrode power supply, said gas supply system, said vacuum system, and said first RF power supply, for controlling the operation of the reactor system.

12. A plasma reactor system for processing a workpiece having an upper surface and an outer edge, comprising:
a) a reactor chamber having an upper wall, a lower wall and sidewalls that define an interior region and capable of supporting a plasma;
b) an upper electrode arranged in said interior region near said upper wall;
c) an upper electrode RF power supply electrically connected to said upper electrode; and
d) the focus ring assembly apparatus according to claim 7.

13. The reactor system according to claim 12, further including a match network arranged between said upper electrode power supply and said upper electrode.

14. The reactor system according to claim 12, further including means for adjusting the position of said focus ring relative to the workpiece upper surface.

15. The reactor system according to claim 12, further including:
a) a gas supply system in pneumatic communication with said interior region;
b) a vacuum system in pneumatic communication with said interior region; and
c) a control system electrically connected to said upper electrode RF power supply, said gas supply system, said vacuum system, and said first RF power supply and said second RF power supply, for controlling the operation of the reactor system.

16. A method of plasma processing a workpiece to a desired standard, the workpiece having an upper surface and an outer edge with a reactor system having a reactor chamber containing a focus ring arranged adjacent the workpiece outer edge and made of a material M and having a profile P, inner and outer radii (R_{I} and R_{O}), the ring being positioned a vertical distance D from the workpiece upper surface, wherein a ring electrode is arranged adjacent the focus ring, the system thus having a set A of variable process parameters {P, R, M, D}, the method comprising the steps of:
a) setting parameters A={P, R, M, D} to initial values; and
b) processing one or more workpieces while varying one or more of said process parameters to determine an optimized set of process parameters A*={P*, R*, M*, D*} that provide the desired processing to within a predetermined standard.

17. The method according to claim 16, wherein the reactor system further has a tuning network electrically connecting the ring electrode to an RF power supply, the tuning network has an indicator with an inductance I and a capacitor with a capacitance C, the parameter set A includes I and C, and the optimized set A* includes I* and C*.

18. A method according to claim 17, wherein said step b) includes the steps of:
i) forming a first plasma within the reactor chamber having characteristics corresponding to said process parameters and processing a first workpiece for a predetermined process time;
ii) measuring the uniformity of the processing of the first workpiece; and
iii) comparing the workpiece process uniformity to a predetermined standard.

19. A method according to claim 18, wherein said step b) further includes the step of:
iv) reducing the workpiece process non-uniformity by changing at least one of said process parameters and repeating said steps i) through iii) using one of said first workpiece or a workpiece other than said first workpiece, until the workpiece process non-uniformity is less than said predetermined standard.

20. A method according to claim 19, wherein said step b) further includes the step of:
v) recording the set of optimized process parameters.

21. A method of processing a workpiece to be processed according to claim 17, further including the steps, after said step b), of:
c) providing a workpiece to be processed in the reactor chamber;
d) forming an optimized plasma with the process chamber using the set of optimized process parameters determined in said step b); and
e) processing the workpiece to be processed with the optimized plasma.
